(19) United States
(12) Patent Application Publication
(10) Pub. No.: US 2025/0347995 A1
(43) Pub. Date: Nov. 13, 2025

(54) SEMICONDUCTOR PHOTORESIST COMPOSITIONS AND METHODS OF FORMING PATTERNS USING THE COMPOSITIONS

(71) Applicant: SAMSUNG SDI CO., LTD., Yongin-si (KR)

(72) Inventors: Sungil MOON, Suwon-si (KR); Joonhee HAN, Suwon-si (KR); Sangkyun IM, Suwon-si (KR); Jun SAKONG, Suwon-si (KR); Hujeong YOON, Suwon-si (KR); Miyeon HAN, Suwon-si (KR)

(21) Appl. No.: 19/063,032

(22) Filed: Feb. 25, 2025

(30) Foreign Application Priority Data
May 7, 2024 (KR) 10-2024-0060065

(51) Int. Cl. G03F 7/004; H01L 21/027; H01L 21/311; H01L 21/3213

(52) U.S. Cl. CPC G03F 7/0042; H01L 21/0275; H01L 21/31144; H01L 21/32139

(57) ABSTRACT

A semiconductor photoresist composition and a method of forming or providing patterns using the semiconductor photoresist composition are disclosed. The semiconductor photoresist composition may include an organometallic compound; a polymer additive including a structural unit represented by Chemical Formula 1; and a solvent.

### CROSS-REFERENCE TO RELATED APPLICATION

The present application claims priority to and the benefit of Korean Patent Application No. 10-2024-0060065, filed on May 7, 2024, in the Korean Intellectual Property Office, the entire disclosure of which is incorporated herein by reference.

### BACKGROUND

### 1. Field

One or more embodiments of the present disclosure relate to a semiconductor photoresist composition and a method of forming or providing patterns using the semiconductor photoresist composition.

### 2. Description of the Related Art

Extreme ultraviolet (EUV) lithography has drawn attention as one technology for manufacturing a next generation semiconductor device. The EUV lithography is a pattern-forming technology using an EUV ray that has a wavelength of 13.5 nm as an exposure light source. According to the EUV lithography, a fine pattern (e.g., less than or equal to 20 nm) may be formed in an exposure process during a manufacture of a semiconductor device (e.g., a semiconductor chip).

The extreme ultraviolet (EUV) lithography is realized through development of compatible photoresists which may be performed at a spatial resolution of less than or equal to 16 nm. Efforts to satisfy insufficient specifications of chemically amplified (CA) photoresists, such as a resolution, a photospeed, and feature roughness (or also referred to as a line edge roughness or LER), for the next generation device have been or are being made.

An intrinsic image blurring due to an acid-catalyzed reaction in the polymer-type or kind of photoresists limits a resolution in small feature sizes which has existed in electron beam (e-beam) lithography. The chemically amplified (CA) photoresists are designed for high sensitivity. However, because their elemental makeups reduce light absorbance of the photoresists at a wavelength of 13.5 nm, it may decrease their sensitivity, and the chemically amplified (CA) photoresists may have more difficulties under an EUV exposure.

The CA photoresists may have difficulties with respect to small feature sizes due to roughness issues, and line edge roughness (LER) of the CA photoresists experimentally may be increased as a photospeed may be decreased partially due to an essence of acid catalyst processes. A novel high-performance photoresist is desired or required in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition has been mainly or predominantly used for negative tone patterning which has resistance against removal by a developer composition due to chemical modification through nonchemical amplification mechanism. The inorganic composition includes an inorganic element that has a higher EUV absorption rate than hydrocarbon, and thus, it may secure sensitivity through the nonchemical amplification mechanism and may be less sensitive with respect to a stochastic effect and thus may have low line edge roughness and a relatively smaller number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. When cationic hafnium metal oxide sulfate (HfSOx) materials along with a peroxo complexing agent were used to image a 15 nm half-pitch (HP) through projection EUV exposure, improved performance was obtained. This system exhibits a high performance of a non-CA photoresist and has a practicable photospeed near to a requirement for an EUV photoresist. However, the hafnium metal oxide sulfate materials including the peroxo complexing agent have some practical drawbacks. First, these materials are coated in a mixture of corrosive sulfuric acid/hydrogen peroxide and have insufficient shelf-life stability. Second, a structural change of the materials for performance improvement as a composite mixture is challenging. Third, development should be performed in a tetramethylammonium hydroxide (TMAH) solution at a high concentration of 25 wt % and/or the like.

To address these issues, research has been focused on developing molecules that include tin (Sn) which have excellent or suitable absorption of extreme ultraviolet rays. As for an organic tin polymer among the molecules containing tin, alkyl ligands are dissociated by light absorption or secondary electrons produced. The dissociated alkyl ligands are then crosslinked with adjacent chains through oxo bonds and thus enable the negative tone patterning which may not be removed by an organic developer. Although this organic tin polymer exhibits improved sensitivity and maintains a desired resolution and line edge roughness, the patterning characteristics may be further improved for commercial availability.

### SUMMARY

One or more aspects of embodiments of the present disclosure are directed toward a semiconductor photoresist composition that has excellent or suitable sensitivity and resolution characteristics, improved or enhanced solubility in a developer, and/or improved or enhanced stability against moisture.

One or more aspects of embodiments of the present disclosure are directed toward a method of forming or providing patterns using the semiconductor photoresist composition.

Additional aspects of embodiments will be set forth in part in the description which follows and, in part, will be apparent from the description, or may be learned by practice of the presented embodiments of the disclosure.

A semiconductor photoresist composition according to one or more embodiments may include an organometallic compound, a polymer additive including a structural unit represented by Chemical Formula 1, and a solvent.

A method of forming or providing patterns according to one or more embodiments may include forming or providing an etching-objective layer on a substrate, coating the semiconductor photoresist composition on the etching-objective layer to form or provide a photoresist film, patterning the photoresist film to form or provide a photoresist pattern, and etching the etching-objective layer utilizing the photoresist pattern as an etching mask.

A pattern formed or provided using the semiconductor photoresist composition according to one or more embodiments may have excellent or suitable sensitivity and resolution and may have improved or enhanced stability against moisture.

### BRIEF DESCRIPTION OF THE DRAWINGS

The above and other aspects and features of certain embodiments of the present disclosure will be more apparent from the following description taken in conjunction with the accompanying drawings, in which:

FIGS. 1A-1E each is a cross-sectional view illustrating a method of forming or providing patterns using a semiconductor photoresist composition according to one or more embodiments.

### DETAILED DESCRIPTION

Hereinafter, referring to the drawings, one or more embodiments of the present disclosure are described in more detail. In the following description of the present disclosure, the functions or constructions that should be generally understood by a person of ordinary skill in the art may not be described in order to clarify the present disclosure.

In order to clearly illustrate embodiments of the present disclosure, certain description and relationships may be omitted, and throughout the present disclosure, substantially the same or similar configuration or arrangement elements may be designated by the same reference numerals. Also, because the size and thickness of each configuration or arrangement shown in the drawings may be arbitrarily shown for better understanding and ease of description, embodiments of the present disclosure are not necessarily limited thereto.

In the drawings, the thickness of layers, films, panels, regions, and/or the like may be enlarged for clarity. In the drawings, the thickness of a part of layers or regions, and/or the like may be exaggerated for clarity. It will be understood that if (e.g., when) an element, such as a layer, film, region, or substrate, is referred to as being “on” another element, it may be directly on the other element or intervening elements may also be present. If (e.g., when) an element is referred to as being “directly on” another element, there may be no intervening elements present.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure.”

In the context of the present disclosure and unless otherwise defined, the terms “use,” “using,” and “used” may be considered synonymous with the terms “utilize,” “utilizing,” and “utilized,” respectively.

As utilized herein, the term “about” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, 20%, 10%, or 5% of the stated value.

Any numerical range recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As used herein, “substituted” refers to replacement of a hydrogen atom by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), −SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, “aliphatic unsaturated organic group” refers to a hydrocarbon group including a bond in which the bond between the carbon and carbon atom in the molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms in the cyclic substituent have a p-orbital, and these p-orbitals are conjugated and may include a monocyclic or fused ring polycyclic functional group (e.g., rings sharing adjacent pairs of carbon atoms).

As used herein, “heteroaryl group” may refer to an aryl group including at least one heteroatom selected from among nitrogen (N), oxygen (O), sulfur (S), phosphorus (P), and silicon (Si). Two or more heteroaryl groups may be linked by a sigma bond directly (e.g., a single covalent bond), or if (e.g., when) the heteroaryl group includes two or more rings, the two or more rings may be fused. If (e.g., when) the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to one or more embodiments is described.

The semiconductor photoresist composition according to one or more embodiments may include an organometallic compound, a polymer additive including a structural unit represented by Chemical Formula 1, and/or a solvent.

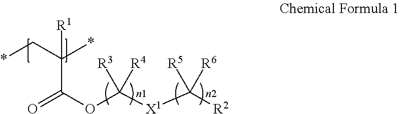

In Chemical Formula 1,
R¹ may be hydrogen or a substituted or unsubstituted C1 to C10 alkyl group,
R² may be a substituted or unsubstituted C1 to C20 alkyl group including a trifluoromethyl group and/or a hydroxyl group,
R³ to R⁶ may each independently be hydrogen, fluorine, a hydroxyl group, a substituted or unsubstituted C1 to C20 alkyl group, or a combination thereof,
n1 and n2 may each independently be an integer of 0 to 10,
n1+n2 may be 1 or more,
X¹ may be a single bond (e.g., a single covalent bond), —O—, —S—, —S(O)—, —S(O)₂—, —C(O)—, —(CO)O—, —O(CO)—, —O(CO)O—, —NR^{a}— (wherein, R^{a} may be hydrogen, deuterium, or a substituted or unsubstituted C1 to C10 alkyl group), or a combination thereof, and
* may be a linking point.

The polymer additive included in the semiconductor photoresist composition may improve or enhance sensitivity and/or LER by including fluorine (e.g., one or more fluorine atoms). For example, due to the hydrophobicity of fluorine (e.g., one or more fluorine atoms) of the polymer additive, the defect improvement or enhancement effect may be excellent or suitable, and stability against moisture may be improved or enhanced.

In one or more embodiments, by including an alkylene chain in the structural unit, solubility of the polymer additive and/or the semiconductor photoresist composition in a developer may be improved or enhanced.

As an example, R² may be a C1 to C20 alkyl group substituted with at least one trifluoromethyl group and/or at least one hydroxyl group.

For example, R² may be a C1 to C20 alkyl group substituted with at least two trifluoromethyl groups and/or at least one hydroxyl group.

For example, R² may be a C1 to C20 alkyl group substituted with two trifluoromethyl groups and/or one hydroxyl group.

In one or more embodiments, R² may be a C1 to C10 alkyl group substituted with two trifluoromethyl groups and/or one hydroxyl group.

In one or more embodiments, R² may be a C1 to C5 alkyl group substituted with two trifluoromethyl groups and/or one hydroxyl group.

In one or more embodiments, R² may be a C1 to C3 alkyl group substituted with two trifluoromethyl groups and/or one hydroxyl group.

In one or more embodiments, R² may be a methyl group substituted with two trifluoromethyl groups and/or one hydroxyl group.

For example, Chemical Formula 1 may be represented by Chemical Formula 1-1.

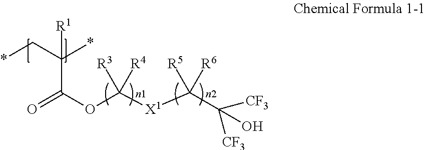

In Chemical Formula 1-1,
R¹ may be hydrogen or a substituted or unsubstituted C1 to C10 alkyl group,
R² may be a substituted or unsubstituted C1 to C20 alkyl group including a trifluoromethyl group and/or a hydroxyl group,
R³ to R⁶ may each independently be hydrogen, fluorine, a hydroxyl group, a substituted or unsubstituted C1 to C20 alkyl group, or a combination thereof,
n1 and n2 may each independently be an integer of 0 to 10,
n1+n2 may be 1 or more,
X¹ may be a single bond (e.g., a single covalent bond), —O—, —S—, —S(O)—, —S(O)₂—, —C(O)—, —(CO)O—, —O(CO)—, —O(CO)O—, —NR^{a}— (wherein, R^{a} may be hydrogen, deuterium, or a substituted or unsubstituted C1 to C10 alkyl group), or a combination thereof, and
* may be a linking point.

If (e.g., when) n1 is 2 or more, each R³ may be the same or different from each other.

If (e.g., when) n1 is 2 or more, each R⁴ may be the same or different from each other.

If (e.g., when) n2 is 2 or more, each R⁵ may be the same or different from each other.

If (e.g., when) n2 is 2 or more, each R⁶ may be the same or different from each other.

For example, the structural unit represented by Chemical Formula 1 may be one selected from among the structural units listed in Group 1.

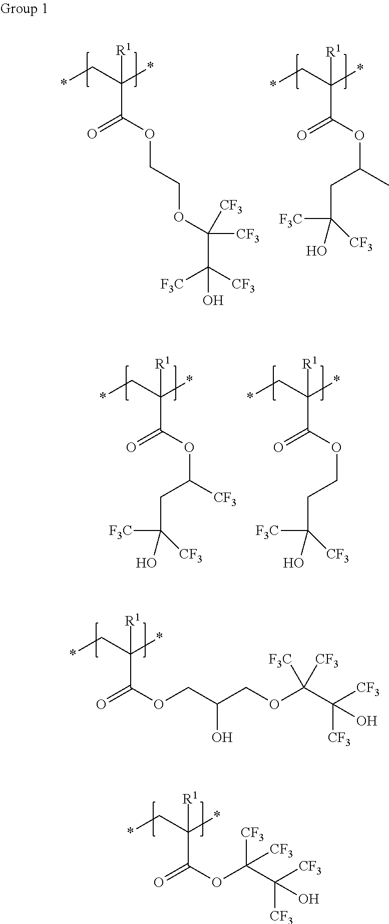

In Group 1,
R¹ may be hydrogen or a methyl group, and
* may be a linking point.

The polymer additive including the structural unit represented by Chemical Formula 1 may be included in an amount of about 0.001 wt % to about 10 wt % based on 100 wt % of the semiconductor photoresist composition.

For example, the polymer additive including the structural unit represented by Chemical Formula 1 may be included in an amount of about 0.01 wt % to about 10 wt %, about 0.01 wt % to about 5 wt %, about 0.05 wt % to about 5 wt %, or about 0.1 wt % to about 5 wt % based on 100 wt % of the semiconductor photoresist composition.

The organometallic compound may be included in an amount of about 0.5 wt % to about 30 wt % based on 100 wt % of the semiconductor photoresist composition.

The semiconductor photoresist composition according to one or more embodiments may improve or enhance the sensitivity of the photoresist by including the organometallic compound and/or the polymer additive including the structural unit represented by Chemical Formula 1 within the above content (e.g., amount) ranges.

The semiconductor photoresist composition according to one or more embodiments may include the organometallic compound and the polymer additive including the structural unit represented by Chemical Formula 1 in a weight ratio of about 99:1 to about 60:40. For example, the semiconductor photoresist composition may include the organometallic compound and the polymer additive including the structural unit represented by Chemical Formula 1 in a weight ratio of about 90:10 to about 60:40.

If (e.g., when) the weight ratio of the organometallic compound and the polymer additive according to one or more embodiments satisfies the above range, the semiconductor photoresist composition having excellent or suitable sensitivity may be provided.

The organometallic compound may be an organic tin (Sn) compound including an organic oxy group and/or an organic carbonyloxy group.

The organometallic compound may be represented by Chemical Formula 2.

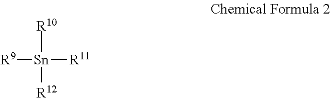

In Chemical Formula 2,
R⁹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R¹⁰ to R¹² may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and Re may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R¹⁰ to R¹² may be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

At least one selected from among R¹⁰ to R¹² may be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In one or more embodiments, the compound represented by Chemical Formula 2 may include —OR^{b} or —OC(═O)R^{c} as a ligand so that a pattern formed or provided by using a semiconductor photoresist composition including the compound may exhibit excellent or suitable limiting resolution.

In one or more embodiments, the —OR^{b} or —OC(═O)R^{c} ligand may suitably adjust or determine the solubility of the compound represented by Chemical Formula 2 in a solvent.
R⁹ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.
R⁹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In one or more embodiments, the tin (Sn)-containing organometallic compound may be represented by Chemical Formula 3 or Chemical Formula 4.

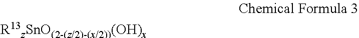

In Chemical Formula 3,
R¹³ may be a C1 to C31 hydrocarbyl group, 0<z≤2, and 0<(z+x)≤4;

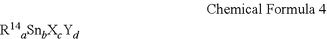

wherein, in Chemical Formula 4,
R¹⁴ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d may each independently be an integer of 1 to 20.

The solvent included in the semiconductor photoresist composition according to one or more embodiments may be an organic solvent, and may be, for example, aromatic compounds (e.g., xylene, toluene, and/or the like), alcohols (e.g., 4-methyl-2-pentanol, 4-methyl-2-propanol, 1-butanol, methanol, isopropyl alcohol, 1-propanol, and/or the like), ethers (e.g., anisole, tetrahydrofuran, and/or the like), esters (n-butyl acetate, propylene glycol monomethyl ether acetate (PGMEA), ethyl acetate, ethyl lactate, and/or the like), ketones (e.g., methyl ethyl ketone, 2-heptanone, and/or the like), or a mixture thereof, but embodiments of the present disclosure are not limited thereto.

The semiconductor photoresist composition according to one or more embodiments may further include a resin in addition to the organometallic compound, polymer additive, and solvent as described in one or more embodiments.

The resin may be a phenol-based resin including at least one aromatic moiety selected from moieties listed in Group 2.

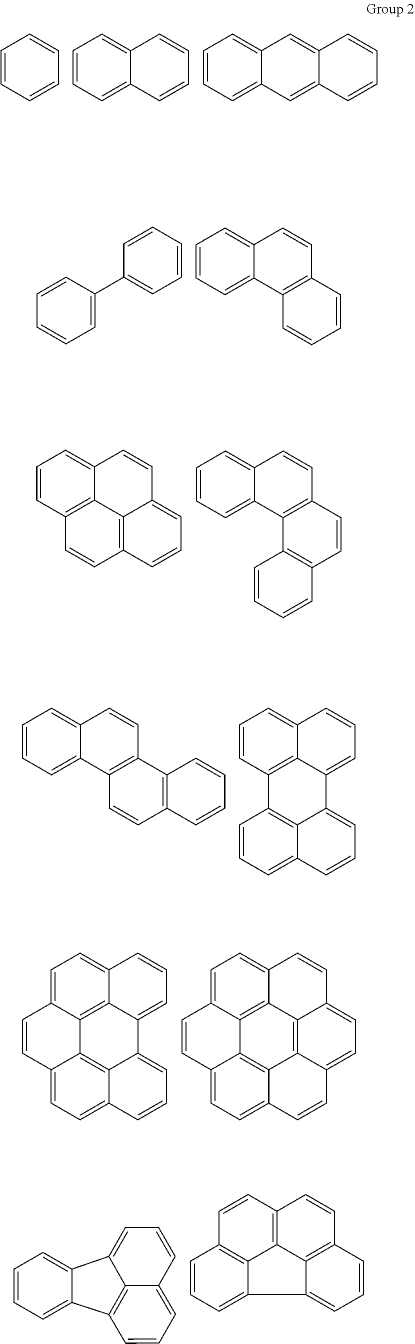

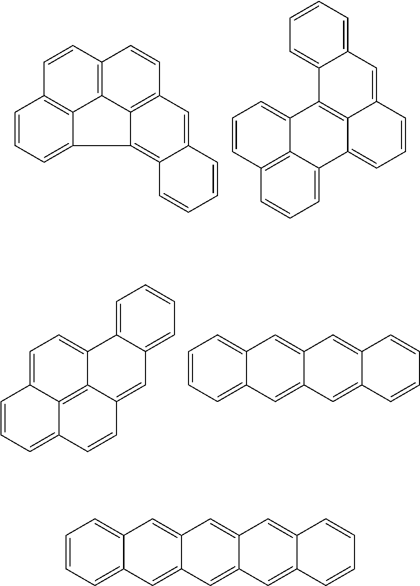

The resin may have a weight average molecular weight (M_{w}) of about 500 g/mol to about 20,000 g/mol.

The resin may be included in an amount of about 0.1 wt % to about 50 wt % based on a total amount of the semiconductor photoresist composition.

If (e.g., when) the resin is included in the above content (e.g., amount) range, the patterns formed or provided by using the semiconductor photoresist composition according to one or more embodiments may have excellent or suitable etch resistance and/or heat resistance.

In one or more embodiments, the semiconductor photoresist composition according to one or more embodiments may consist of (or may include) the organometallic compound, polymer additive, solvent, and/or resin as described in one or more embodiments.

In one or more embodiments, the semiconductor photoresist composition according to one or more embodiments may further include additives as needed or desired. Examples of the additives may be a surfactant, a crosslinking agent, a leveling agent, an organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, and/or a polymer-based crosslinking agent, but embodiments of the present disclosure are not limited thereto. It may be a crosslinking agent having at least two crosslinking forming substituents, for example, methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, ether, trimethylpropane triglycidyl 1,3-bis(glycidoxypropyl)tetramethyldisiloxane, methoxymethylated urea, butoxymethylated urea, methoxymethylated thiourea, and/or the like.

The leveling agent may be used to improve or enhance coating flatness during printing and may be a commercially available or generally available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

A use amount of the additives may be suitably controlled or adjusted depending on suitable or desired properties.

In one or more embodiments, the semiconductor photoresist composition may further include a silane coupling agent as an adherence enhancer in order to improve or enhance a close-contacting force with the substrate (e.g., in order to improve or enhance adherence of the semiconductor photoresist composition to the substrate). The silane coupling agent may be, for example, a silane compound including a carbon-carbon unsaturated bond, such as vinyltrimethoxysilane, vinyl triethoxysilane, vinyl trichlorosilane, vinyl tris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but embodiments of the present disclosure are not limited thereto.

The semiconductor photoresist composition may be formed or provided into a pattern having a high aspect ratio without a collapse. In one or more embodiments, in order to form or provide a fine pattern having a width (e.g., a line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or, for example, about 5 nm to about 20 nm, the semiconductor photoresist composition may be used for a photoresist process using light having a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. In one or more embodiments, the semiconductor photoresist composition according to one or more embodiments may be used to realize or provide extreme ultraviolet lithography using an EUV light source of a wavelength of about 13.5 nm.

According to one or more embodiments, a method of forming or providing patterns using the semiconductor photoresist composition as described in one or more embodiments is provided. For example, the manufactured pattern may be a photoresist pattern.

The method of forming or providing patterns according to one or more embodiments may include forming or providing an etching-objective layer on a substrate, coating the semiconductor photoresist composition on the etching-objective layer to form or provide a photoresist film, patterning the photoresist film to form or provide a photoresist pattern, and etching the etching-objective layer utilizing the photoresist pattern as an etching mask.

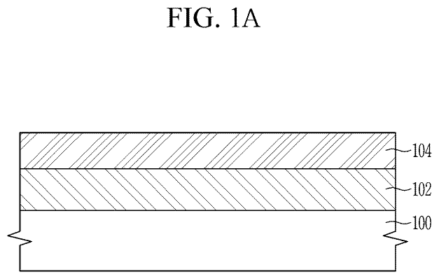

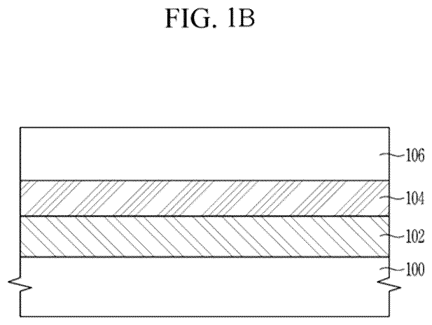

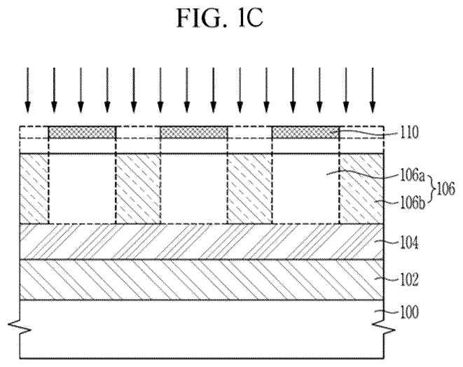

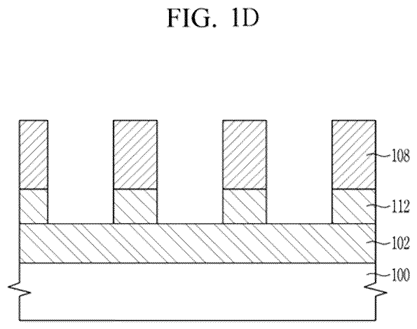

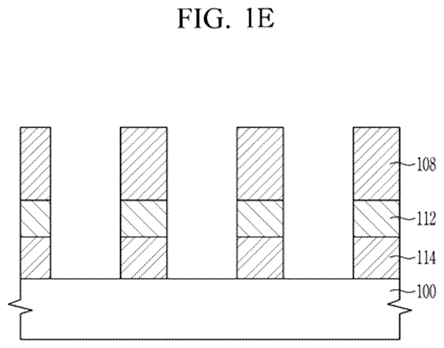

Hereinafter, a method of forming or providing patterns using the semiconductor photoresist composition is described referring to FIGS. 1A-1E. FIGS. 1A-1E each is a cross-sectional view illustrating a method of forming or providing patterns using a semiconductor photoresist composition according to one or more embodiments.

Referring to FIG. 1A, an object for etching (e.g., etching-objective layer or etching-target layer) may be prepared. The object for etching may be a thin film 102 that may be formed or provided on a semiconductor substrate 100. Hereinafter, the object for etching may be limited to the thin film 102. A surface of the thin film 102 may be washed to remove impurities and/or the like remaining thereon. The thin film 102 may be, for example, a silicon nitride layer, a polysilicon layer, and/or a silicon oxide layer.

Subsequently, the resist underlayer composition to form or provide a resist underlayer 104 may be spin-coated on the surface of the washed thin film 102. However, embodiments of the present disclosure are not limited thereto, and one or more suitable coating methods, for example, a spray coating, a dip coating, a knife edge coating, a printing method, for example, an inkjet printing and/or a screen printing, and/or the like, may be used.

The coating process of the resist underlayer may not be provided, and hereinafter, a process including a coating of the resist underlayer is described.

Then, the coated composition may be dried and baked to form or provide a resist underlayer 104 on the thin film 102. The baking (e.g., thermal treatment) may be performed at about 100° C. to about 500° C., for example, about 100° C. to about 300° C.

The resist underlayer 104 may be formed or provided between the substrate 100 and the photoresist film 106 and thus may prevent or reduce non-uniformity (e.g., substantial non-uniformity) and pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 may be formed or provided by coating the semiconductor photoresist composition on the resist underlayer 104. The photoresist film 106 may be obtained or provided by coating the semiconductor photoresist composition according to one or more embodiments on the thin film 102 that may be formed or provided on the substrate 100 and then, curing it through a heat treatment.

For example, the formation of a pattern by using the semiconductor photoresist composition may include coating the semiconductor resist composition on the substrate 100 having the thin film 102 through spin coating, slit coating, inkjet printing, and/or the like, and then, drying it to form or provide the photoresist film 106.

The semiconductor photoresist composition has already been illustrated in more detail and may not be illustrated again.

Subsequently, a substrate 100 having the photoresist film 106 may be subjected to a first baking process (e.g., thermal treatment). The first baking process may be performed at about 80° C. to about 120° C.

Referring to FIG. 1C, the photoresist film 106 may be selectively exposed using a patterned mask 110.

For example, the exposure may use an activation radiation including light or beam having a high energy wavelength, such as EUV (extreme ultraviolet; a wavelength of about 13.5 nm), an E-Beam (an electron beam), and/or the like, as well as light having a short wavelength, such as an i-line (a wavelength of about 365 nm), a KrF excimer laser (a wavelength of about 248 nm), an ArF excimer laser (a wavelength of about 193 nm), and/or the like.

For example, light or beam for the exposure according to one or more embodiments may have a short wavelength in a range of about 5 nm to about 150 nm and a high energy wavelength, for example, EUV (extreme ultraviolet; a wavelength of 13.5 nm), an E-Beam (an electron beam), and/or the like.

The exposed region 106b of the photoresist film 106 may have a different solubility from the unexposed region 106a of the photoresist film 106 by forming or providing a polymer by a crosslinking reaction, such as condensation between organometallic compounds (e.g., a condensation reaction between organometallic compounds).

Subsequently, the substrate 100 may be subjected to a second baking process (e.g., thermal treatment). The second baking process may be performed at a temperature of about 90° C. to about 200° C. The exposed region 106b of the photoresist film 106 may become easily indissoluble regarding a developer due to the second baking process.

In FIG. 1D, the unexposed region 106a of the photoresist film may be dissolved and removed by using the developer to form or provide a photoresist pattern 108. For example, the unexposed region 106a of the photoresist film may be dissolved and removed by using an organic solvent, such as 2-heptanone and/or the like, to complete the photoresist pattern 108 corresponding to the negative tone image.

According to one or more embodiments, a developer used in a method of forming or providing patterns according to one or more embodiments may be an organic solvent. The organic solvent used in the method of forming or providing patterns according to one or more embodiments may be, for example, ketones, such as methylethylketone, acetone, cyclohexanone, 2-heptanone, and/or the like, alcohols, such as 4-methyl-2-propanol, 1-butanol, isopropanol, 1-propanol, methanol, and/or the like, esters, such as propylene glycol monomethyl ether acetate, ethyl acetate, ethyl lactate, n-butyl acetate, butyrolactone, and/or the like, aromatic compounds, such as benzene, xylene, toluene, and/or the like, or a combination thereof.

However, the photoresist pattern according to one or more embodiments is not necessarily limited to the negative tone image but may be formed or provided to have a positive tone image. Herein, a developer used to form or provide the positive tone image may be a quaternary ammonium hydroxide composition, such as tetraethylammonium hydroxide, tetrapropylammonium hydroxide, tetrabutylammonium hydroxide, or a combination thereof.

According to one or more embodiments, exposure to light or beam having a high energy wavelength, such as EUV (extreme ultraviolet; a wavelength of 13.5 nm), an E-Beam (an electron beam), and/or the like, as well as light having a short wavelength, such as i-line (wavelength of about 365 nm), KrF excimer laser (wavelength of about 248 nm), ArF excimer laser (wavelength of about 193 nm), and/or the like, may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch having (with) a half-pitch of less than or equal to about 50 nm, for example, less than or equal to about 40 nm, for example, less than or equal to about 30 nm, for example, less than or equal to about 20 nm, or, for example, less than or equal to about 15 nm, and a line width roughness of less than or equal to about 10 nm, or less than or equal to about 5 nm, less than or equal to about 3 nm, or less than or equal to about 2 nm.

Subsequently, the photoresist pattern 108 may be used as an etching mask to etch the resist underlayer 104. Through this etching process, an organic film pattern 112 may be formed or provided. The organic film pattern 112 also may have a width (e.g., a line width) corresponding to that of the photoresist pattern 108.

Referring to FIG. 1E, the exposed thin film 102 may be etched by applying the photoresist pattern 108 as an etching mask. As a result, the thin film may be formed or provided as a thin film pattern 114.

The etching of the thin film 102 may be, for example, dry etching using an etching gas, and the etching gas may be, for example, CHF₃, CF₄, Cl₂, BCl₃, and a mixed gas thereof.

In the exposure process, the thin film pattern 114 formed or provided by utilizing the photoresist pattern 108 that may be formed or provided through the exposure process performed by using an EUV light source may have a width (e.g., a line width) corresponding to that of the photoresist pattern 108. For example, the thin film pattern 114 may have a width (e.g., a line width) of about 5 nm to about 100 nm which may be equal to that of the photoresist pattern 108. For example, the thin film pattern 114 formed or provided by utilizing the photoresist pattern 108 that may be formed or provided through the exposure process performed by using an EUV light source may have a width (e.g., a line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width (e.g., a line width) of less than or equal to about 20 nm, like or similar to that of the photoresist pattern 108.

Hereinafter, the subject matter of the present disclosure will be described in more detail through examples of the preparation of the semiconductor photoresist composition as described in one or more embodiments of the present disclosure.

However, one or more embodiments of the present disclosure are technically not restricted by the following examples.

### SYNTHESIS OF ORGANOMETALLIC COMPOUND

### Synthesis Example 1

40.7 g of t-butylSnPhs and 300 g of propionic acid were added to a 250 mL 2-necked round-bottomed flask and then, refluxed by heating for 24 hours.

A resultant compound represented by Chemical Formula 5 was obtained by removing the unreacted propionic acid under a reduced pressure therefrom.

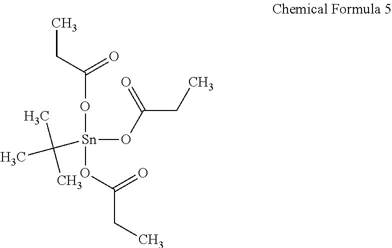 [SMILES: CCC(=O)[O][Sn]([O]C(=O)CC)([O]C(=O)CC)[C](C)(C)C]

### Synthesis Example 2

After adding 30 mL of anhydrous pentane to 10 g of t-AmylSnCl₃ and maintaining their temperature at 0° C., 7.4 g of diethyl amine and 6.1 g of ethanol were added thereto and then, stirred at room temperature for 1 hour. When a reaction was completed, the resultant was filtered, concentrated, and vacuum-dried, obtaining a compound represented by Chemical Formula 6.

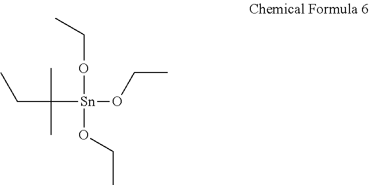

### Synthesis Example 3

10 g of dibutyltin dichloride was dissolved in 30 mL of ether, 70 mL of a 1 M sodium hydroxide (NaOH) aqueous solution was added thereto and then, stirred for 1 hour. After stirring, a solid produced therein was filtered, washed with 25 mL of deionized water three times, and dried at 100° C. under a reduced pressure to obtain an organometallic compound represented by Chemical Formula 7 and having a weight average molecular weight (M_{w}) of 1,500 g/mol.

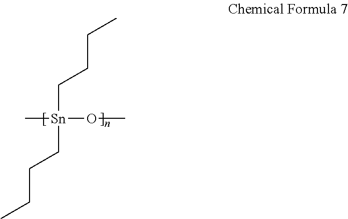

### Synthesis Example 4: Synthesis of Compound 1a

Under a nitrogen atmosphere, 20 g (59.86 mmol) of hexafluoromethyl-2,3-bis(trifluoromethyl)-2,3-butanediol(perfluoropinacol), 7.79 g (59.86 mmol) of 2-(hydroxyethyl) methacrylate, and 18.84 g (71.84 mmol) of triphenylphosphine (Ph₃P) were mixed in 110 mL of diethyl ether and then, stirred. After stirring for 30 minutes, the resultant mixture was cooled to 0° C., and another mixture of 14.52 g (71.84 mmol) of diisopropyl azodicarboxylate (DIAD) and 35 mL of diethyl ether was slowly added in a dropwise fashion thereto over 2 hours. Subsequently, the obtained mixture was stirred at room temperature (23° C.) for 24 hours and then, concentrated. The concentrated mixture was dissolved in dichloromethane and then, treated through column chromatography using silica gel to separate a synthesized material. The separated material wad distilled again under a reduced pressure to synthesize 2-[3,3,3-trifluoro-2-hydroxy-1, 1,2-tris(trifluoromethyl)propoxy]ethyl 2-methyl-2-propenoate represented by Chemical Formula 1a.

¹H-NMR (Acetone-d6): δ1.90 (3H, t), 4.36 (4H, m), 5.63 (1H, t), 6.09 (1H, t), 8.34 (1H,s)

¹⁹F-NMR (Acetone-d6): δ-70.12 (6F, m),-65.38 (6F, m)

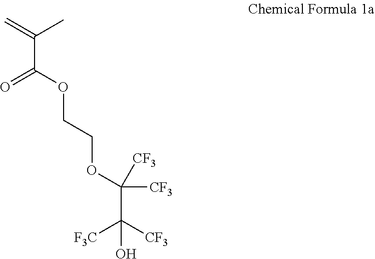 [SMILES: C=C(C)C(=O)OCCOC(C(F)(F)F)(C(F)(F)F)C(O)(C(F)(F)F)C(F)(F)F]

### Synthesis Example 5: Preparation of Polymer R1

In a 250 mL 2-neck round bottom flask, under a nitrogen atmosphere, a compound represented by Chemical Formula 1a (16.1 g, 36 mmol) and 110 g of diisoamyl ether (DIAE) were added thereto and then, heated to an internal temperature of 85° C. When the internal temperature reached 85° C., 14.7 g of a 25 wt % V-601/DIAE solution (3.7 g, 16 mmol of V-601) was slowly added thereto, and after 6 hours, the resultant reaction solution was cooled to room temperature and then, concentrated to 50% of a solid content (e.g., amount). Then, 270 g of heptane was added to the concentrated solution, filtering a polymer produced therein. The filtered polymer was completely dissolved in 34 g of DIAE and then, precipitated by adding 270 g of heptane thereto, which was repeated twice, and then, completely dried, finally obtaining Polymer R1 (M_{w}=5,000 g/mol).

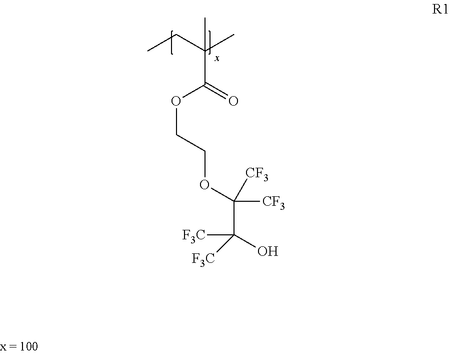

### Synthesis Example 6: Preparation of Polymer R2

Polymer R2 (M_{w}=5,500) was obtained in substantially the same manner as in Synthesis Example 5 except that 8.83 g of a compound represented by Chemical Formula 1b (HALOCARBON, LLC) was used instead of a compound represented by Chemical Formula 1a.

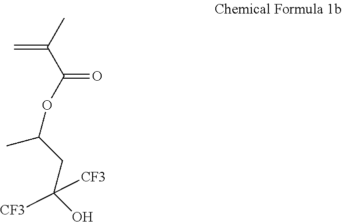 [SMILES: C=C(C)C(=O)OC(C)CC(O)(C(F)(F)F)C(F)(F)F]

### Synthesis Example 7: Preparation of Polymer R3

Polymer R3 (M_{w}=5,500) was obtained in substantially the same manner as in Synthesis Example 5 except that 20 g of a compound represented by Chemical Formula 1c (HALOCARBON, LLC) was used instead of a compound represented by Chemical Formula 1a.

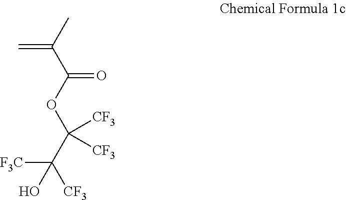 [SMILES: C=C(C)C(=O)OC(C(F)(F)F)(C(F)(F)F)C(O)(C(F)(F)F)C(F)(F)F]

### Synthesis Example 8: Preparation of Polymer R4

Polymer R4 (M_{w}=5,300) was obtained in substantially the same manner as in Synthesis Example 5 except that 20 g of a compound represented by Chemical Formula 1d (HALOCARBON, LLC) was used instead of a compound represented by Chemical Formula 1a.

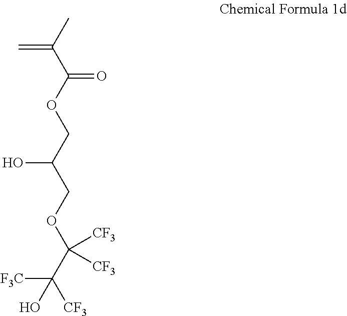 [SMILES: C=C(C)C(=O)OCC(O)COC(C(F)(F)F)(C(F)(F)F)C(O)(C(F)(F)F)C(F)(F)F]

### Synthesis Example 9: Preparation of Polymer R5

Polymer R5 (M_{w}=5,300) was obtained in substantially the same manner as in Synthesis Example 5 except that 20 g of a compound represented by Chemical Formula 1e (HALOCARBON, LLC) was used instead of a compound represented by Chemical Formula 1a.

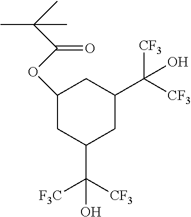 [SMILES: CC(C)(C)C(=O)OC1CC(C(O)(C(F)(F)F)C(F)(F)F)CC(C(O)(C(F)(F)F)C(F)(F)F)C1]

### PREPARATION OF SEMICONDUCTOR PHOTORESIST COMPOSITIONS

### Examples 1 to 15 and Comparative Examples 1 to 4

The organometallic compounds represented by Chemical Formulas 5 to 7 according to Synthesis Examples 1 to 3 and Polymer R1 to R5 according to Synthesis Examples 5 to 9 were respectively dissolved in propylene glycol methyl ether acetate (PGMEA) in a weight ratio shown in Table 1 at a concentration of 3 wt % and then, filtered with a 0.1 μm polytetrafluoroethylene (PTFE) syringe filter, preparing semiconductor photoresist compositions according to Examples 1 to 15 and Comparative Examples 1 to 4.

TABLE 1

| | Organometallic compound | Polymer additive |
|---|---|---|
| | (wt %) | (wt %) |
| Comparative | Chemical Formula 5 | — |
| Example 1 | (3.00) | |
| Example 1 | Chemical Formula 5 | R1 |
| | (2.5) | (0.5) |
| Example 2 | Chemical Formula 5 | R1 |
| | (2.0) | (1.0) |
| Example 3 | Chemical Formula 5 | R2 |
| | (2.0) | (1.0) |
| Example 4 | Chemical Formula 5 | R3 |
| | (2.0) | (1.0) |
| Example 5 | Chemical Formula 5 | R4 |
| | (2.0) | (1.0) |
| Comparative | Chemical Formula 6 | — |
| Example 2 | (3.0) | |
| Example 6 | Chemical Formula 6 | R1 |
| | (2.5) | (0.5) |
| Example 7 | Chemical Formula 6 | R1 |
| | (2.0) | (1.0) |
| Example 8 | Chemical Formula 6 | R2 |
| | (2.0) | (1.0) |
| Example 9 | Chemical Formula 6 | R3 |
| | (2.0) | (1.0) |
| Example 10 | Chemical Formula 6 | R4 |
| | (2.0) | (1.0) |
| Comparative | Chemical Formula 7 | — |
| Example 3 | (3.0) | |
| Comparative | Chemical Formula 7 | R5 |
| Example 4 | (2.5) | (0.5) |
| Example 11 | Chemical Formula 7 | R1 |
| | (2.5) | (0.5) |
| Example 12 | Chemical Formula 7 | R1 |
| | (2.0) | (1.0) |
| Example 13 | Chemical Formula 7 | R2 |
| | (2.0) | (1.0) |
| Example 14 | Chemical Formula 7 | R3 |
| | (2.0) | (1.0) |
| Example 15 | Chemical Formula 7 | R4 |
| | (2.0) | (1.0) |

### Evaluation 1: Evaluation of Sensitivity and Line Edge Roughness (LER)

Each of the photoresist compositions according to Examples and Comparative Examples was spin-coated for 30 seconds at 1500 rpm, respectively, on a 200 mm circular silicon wafer whose surface was deposited with hexamethyldisilazane (HMDS), and baked at 110° C. for 60 seconds. After application, it was baked (post-apply bake, PAB) and then left at room temperature (23±2° C.) for 30 seconds.

Afterwards, a linear array of 50 circular pads having a diameter of 500 μm was projected onto the wafer coated with the photoresist composition by using EUV light (Lawrence Berkeley National Laboratory Micro Exposure Tool, MET). Herein, pad exposure time was adjusted to ensure that the EUV light in an increased dose was applied to each pad.

Then, the resist and the substrate were baked at 160° C. for 120 seconds on a hot plate after the exposure. The baked film was developed with a PGMEA solvent to form or provide a negative tone image. Finally, the obtained film was baked again at 150° C. for 2 minutes on the hot plate, completing the process.

The remaining resist thickness of the exposed pad was measured using an ellipsometer. The remaining thickness was measured for each exposure dose and then, graphed as a function to the exposure doses to measure sensitivity, and measuring LER was measured from field emission scanning electron microscopy (FE-SEM) image to evaluate line edge roughness, and then, the sensitivity and the line edge roughness were evaluated according to the following criteria, and the results are shown in Table 2.

### Sensitivity Evaluation Criteria

A: less than 50 mJ/cm²
B: greater than or equal to 50 mJ/cm²

### LER Evaluation Criteria

○: less than or equal to 2 nm
Δ: greater than 2 nm and less than or equal to 5 nm
X: greater than 5 nm

### Evaluation 2: Evaluation of Defects

On a 12-inch silicon substrate, a lower silicon oxynitride (SiON) film/a spin-on carbon film/an upper SiON film in order were formed or provided. On the upper SiON film, each of the photoresist compositions according to Examples and Comparative Examples was used to form or provide a 1:1 line/space photoresist pattern having a pitch of 36 nm in an EUV lithography method. The photoresist pattern was transferred to the lower SiON film through dry etching using a plasma. Then, all defects, including bridge defects between the line patterns, were inspected in a bright field by using a defect analysis equipment using a DUV laser. The inspected defects were classified by using scanning electron microscopy (SEM) and then, shown as the number of the classified defects per unit area (ea/cm²).

Herein, when the number of single line open (SLO) defects in the case of (e.g., when) not applying each of the photoresist compositions was converted to 100, if (e.g., when) the number of defects was less than or equal to 80%, ‘○’ was given, and if (e.g., when) the number of defects was greater than 80%, ‘X’ was given.

TABLE 2

| | Sensitivity | LER | Defect evaluation |
|---|---|---|---|
| Example 1 | A | ◯ | ◯ |
| Example 2 | A | ◯ | ◯ |
| Example 3 | A | ◯ | ◯ |
| Example 4 | A | ◯ | ◯ |
| Example 5 | A | ◯ | ◯ |
| Example 6 | A | ◯ | ◯ |
| Example 7 | A | ◯ | ◯ |
| Example 8 | A | ◯ | ◯ |
| Example 9 | A | ◯ | ◯ |
| Example 10 | A | ◯ | ◯ |
| Example 11 | A | ◯ | ◯ |
| Example 12 | A | ◯ | ◯ |
| Example 13 | A | ◯ | ◯ |
| Example 14 | A | ◯ | ◯ |
| Example 15 | A | ◯ | ◯ |
| Comparative Example 1 | B | X | X |
| Comparative Example 2 | B | Δ | X |
| Comparative Example 3 | B | X | X |
| Comparative Example 4 | B | Δ | Δ |

From the results in Table 2, the patterns formed or provided by using the semiconductor photoresist compositions according to Examples 1 to 15 exhibited excellent sensitivity, LER, and resolution characteristics compared to Comparative Examples 1 to 4.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. Accordingly, the modified or transformed embodiments as such may not be understood separately from the technical ideas and aspects of one or more embodiments of the present disclosure, and the modified embodiments may be within the scope of the appended claims and equivalents thereof of the present disclosure.

Description of Symbols

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising:
an organometallic compound;
a polymer additive comprising a structural unit represented by Chemical Formula 1; and
a solvent: 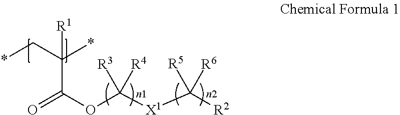
wherein, in Chemical Formula 1,
R¹ is hydrogen or a substituted or unsubstituted C1 to C10 alkyl group,
R² is a substituted or unsubstituted C1 to C20 alkyl group including a trifluoromethyl group and a hydroxyl group,
R³ to R⁶ are each independently hydrogen, fluorine, a hydroxyl group, a substituted or unsubstituted C1 to C20 alkyl group, or a combination thereof,
n1 and n2 are each independently an integer of 0 to 10,
n1+n2 is 1 or more,
X¹ is a single bond, —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof, and
* is a linking point.

2. The semiconductor photoresist composition as claimed in claim 1, wherein:
R² is a C1 to C20 alkyl group substituted with at least one trifluoromethyl group and at least one hydroxyl group.

3. The semiconductor photoresist composition as claimed in claim 1, wherein:
R² is a C1 to C10 alkyl group substituted with two trifluoromethyl groups and one hydroxyl group.

4. The semiconductor photoresist composition as claimed in claim 1, wherein:
Chemical Formula 1 is represented by Chemical Formula 1-1: 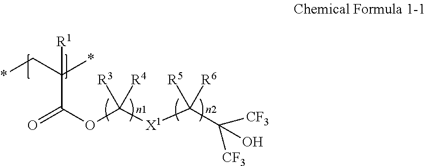
wherein, in Chemical Formula 1-1,
R¹ is hydrogen or a substituted or unsubstituted C1 to C10 alkyl group,
R³ to R⁶ are each independently hydrogen, fluorine, a hydroxyl group, a substituted or unsubstituted C1 to C20 alkyl group, or a combination thereof,
n1 and n2 are each independently an integer of 0 to 10,
n1+n2 is 1 or more,
X¹ is a single bond, —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof, and
* is a linking point.

5. The semiconductor photoresist composition as claimed in claim 1, wherein:
the structural unit represented by Chemical Formula 1 is one selected from among the structural units listed in Group 1: 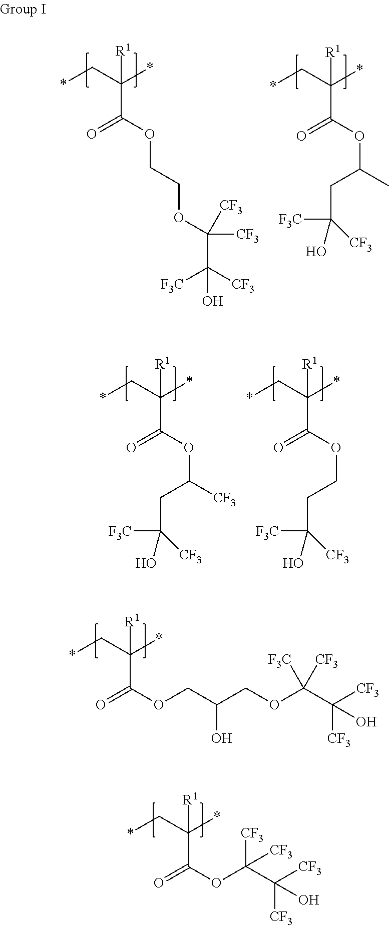
wherein, in Group 1,
R¹ is hydrogen or a methyl group, and
* is a linking point.

6. The semiconductor photoresist composition as claimed in claim 1, wherein:
the polymer additive comprising the structural unit represented by Chemical Formula 1 is included in an amount of about 0.001 wt % to about 10 wt % based on 100 wt % of the semiconductor photoresist composition.

7. The semiconductor photoresist composition as claimed in claim 1, wherein:
the polymer additive comprising the structural unit represented by Chemical Formula 1 is included in an amount of about 0.1 wt % to about 5 wt % based on 100 wt % of the semiconductor photoresist composition.

8. The semiconductor photoresist composition as claimed in claim 1, wherein:
the organometallic compound is included in an amount of about 0.5 wt % to about 30 wt % based on 100 wt % of the semiconductor photoresist composition.

9. The semiconductor photoresist composition as claimed in claim 1, wherein:
the semiconductor photoresist composition further comprises an additive of a surfactant, a crosslinking agent, a leveling agent, an organic acid, a quencher, or a combination thereof.

10. The semiconductor photoresist composition as claimed in claim 1, wherein:
the organometallic compound is an organic tin (Sn) compound comprising at least one selected from an organic oxy group and an organic carbonyloxy group.

11. The semiconductor photoresist composition as claimed in claim 1, wherein:
the organometallic compound is represented by Chemical Formula 2: 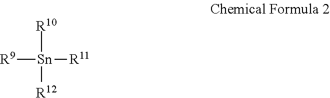
wherein, in Chemical Formula 2 ,
R⁹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R¹⁰ to R¹² are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R¹⁰ to R¹² is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

12. The semiconductor photoresist composition as claimed in claim 11, wherein:
at least one selected from among R¹⁰ to R¹² is selected from among an alkoxy or aryloxy group (—OR^{b}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

13. The semiconductor photoresist composition as claimed in claim 12, wherein:
R⁹ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

14. The semiconductor photoresist composition as claimed in claim 1, wherein:
the organometallic compound is represented by Chemical Formula 3 or Chemical Formula 4: 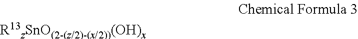
wherein, in Chemical Formula 3,
R¹³ is a C1 to C31 hydrocarbyl group, 0<z≤2, and 0<(z+x)≤4; 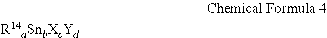
wherein, in Chemical Formula 4,
R¹⁴ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te), and
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

15. A method of forming patterns, comprising:
providing an etching-objective layer on a substrate;
coating the semiconductor photoresist composition as claimed in claim 1 on the etching-objective layer to provide a photoresist film;
patterning the photoresist film to provide a photoresist pattern; and
etching the etching-objective layer utilizing the photoresist pattern as an etching mask.
